(19) United States
(12) Patent Application Publication
(10) Pub. No.: US 2024/0132714 A1
(43) Pub. Date: Apr. 25, 2024

(54) EPOXY RESIN COMPOSITION, SEMICONDUCTOR DEVICE, AND METHOD OF PRODUCING SEMICONDUCTOR DEVICE

(71) Applicant: NAMICS CORPORATION, Niigata-shi, Niigata (JP)

(72) Inventors: Yuki MATSUURA, Niigata (JP); Ayako SATO, Niigata (JP); Tomoya YAMAZAWA, Niigata (JP)

(73) Assignee: NAMICS CORPORATION, Niigata-shi, Niigata (JP)

(21) Appl. No.: 18/277,309

(22) PCT Filed: Jun. 22, 2022
(86) PCT No.: PCT/JP2022/024883

§ 371 Date: Aug. 15, 2023

(30) Foreign Application Priority Data
Jun. 29, 2021 (JP) 2021-107204

(51) Int. Cl. C08L 63/00; H01L 21/56; H01L 23/29

(52) U.S. Cl. CPC C08L 63/00; H01L 21/563; H01L 23/295; C08K 2201/003

(57) ABSTRACT

To suppress the bias of the distribution of a filler dispersed in a sealing material (cured product) covering an electrode connection portion, provided is an epoxy resin composition, including: (A) an epoxy resin; (B) a curing agent; (C) a filler; and (D) an ionic compound in which at least one of a cation or an anion is organic matter.

### CROSS REFERENCE TO RELATED APPLICATIONS

This application is a U.S. National Phase Application under 35 U.S.C. 371 of International Application No. PCT/JP2022/024883, filed on Jun. 22, 2022, which claims priority to Japanese Patent Application No. 2021-107204, filed on Jun. 29, 2021. The entire disclosures of the above applications are expressly incorporated by reference herein.

### BACKGROUND

### Technical Field

The present invention relates to an epoxy resin composition, a semiconductor device, and a method of producing a semiconductor device.

### Related Art

Flip-chip mounting has been known as a technology for the mounting of a semiconductor element on a substrate. The flip-chip mounting is a mounting method in which a semiconductor element having a projecting electrode (element-side electrode) called a bump formed on its surface is used to directly connect the element-side electrode of the semiconductor element and an electrode (substrate-side electrode) arranged on the surface of the substrate such as a wiring substrate to each other. In addition, in the flip-chip mounting, to protect the semiconductor element, the substrate connected to the semiconductor element, and the bump, an underfill is filled into a space between the semiconductor element and the substrate, and is then heated and cured.

An epoxy resin composition including an epoxy resin as its main component is mainly used as the underfill (see, for example, JP 2017-145290 A). Meanwhile, the epoxy resin, the semiconductor element, and the substrate have linear expansion coefficients different from each other. Accordingly, when a stress occurring in an electrode connection portion between the element-side electrode and the substrate-side electrode along with a temperature change cannot be absorbed by a sealing material (the cured product of the underfill) covering the electrode connection portion, a crack may occur in the connection portion. To suppress the occurrence of the crack, a filler formed of, for example, silica or alumina having a relatively small linear expansion coefficient is also typically blended into the underfill in addition to the epoxy resin.

Meanwhile, in flip-chip mounting in recent years, from the viewpoint of, for example, narrowing a pitch, a metal pillar such as a copper pillar has started to be used as a member for forming an electrode instead of the bump. In addition, in such flip-chip mounting, it has been known that in a process for the heating and curing of the underfill filled so as to cover the connection portion, the separation and aggregation of the filler uniformly dispersed in the underfill advance, and hence the underfill is immediately cured in some cases. In addition, in the case where such phenomenon occurs, when the filler dispersed in the sealing material (the cured product of the underfill) covering the electrode connection portion is distributed under the state of being biased toward the semiconductor element or the substrate with respect to the connection interface of the electrode connection portion, connection reliability reduces. In addition, such separation and aggregation of the filler, and such bias of the filler distribution are assumed to be due to the electrophoresis of the filler in the underfill, which is filled so as to surround the electrode connection portion, by a potential difference occurring as a result of the fact that a material for forming an element-side electrode connection surface and a material for forming a substrate-side electrode connection surface are different from each other. Accordingly, an epoxy resin composition suitable for suppressing the bias of the filler distribution in the sealing material has been proposed (WO 2015/079708 A1). The epoxy resin composition includes 0.1 mass % to 10 mass % of a first silica filler having an average particle diameter of from 10 nm to 100 nm, 47 mass % to 75 mass % of a second silica filler having an average particle diameter of from 0.3 μm to 2 μm, and 0.1 mass % to 8 mass % of an elastomer in addition to an epoxy resin and a curing agent, and includes 50.1 mass % to 77 mass % of the first silica filler and the second silica filler in total.

The technology described in WO 2015/079708 A1 is a technology useful in improving the connection reliability. However, in the technology described in WO 2015/079708 A1, predetermined amounts of the two kinds of silica fillers having predetermined particle diameters and the elastomer need to be used for improving the connection reliability, and in this respect, certain constraints are imposed on the composition design of the epoxy resin composition. Accordingly, an increase in number of choices of the composition design has been required with a view to further facilitating correspondence to various other needs while improving the connection reliability as in the technology described in WO 2015/079708 A1.

The present invention has been made in view of the above-mentioned circumstances, and an object of the present invention is to provide an epoxy resin composition having novel composition, the composition being capable of suppressing the bias of the distribution of a filler dispersed in a sealing material (cured product) covering an electrode connection portion, a semiconductor device produced by using the composition, and a method of producing the semiconductor device.

### SUMMARY

The above-mentioned object is achieved by the present invention described below. That is, according to one embodiment of the present invention, there is provided an epoxy resin composition, including: (A) an epoxy resin; (B) a curing agent; (C) a filler; and (D) an ionic compound.

In the epoxy resin composition according to one embodiment of the present invention, it is preferred that (D) the ionic compound contain at least one selected from the group consisting of: a pyridinium-based ionic compound; an imidazolium-based ionic compound; an ammonium-based ionic compound; a phosphonium-based ionic compound; a pyrrolidinium-based ionic compound; a piperidinium-based ionic compound; a sulfonate-based ionic compound; and an iodine-based ionic compound.

In the epoxy resin composition according to another embodiment of the present invention, it is preferred that (D) the ionic compound contain <i>at least one kind of cation selected from the group consisting of: a pyridinium-based cation; an imidazolium-based cation; an ammonium-based cation; a pyrrolidinium-based cation; a piperidinium-based cation; and a phosphonium-based cation, and <ii>at least one kind of anion selected from the group consisting of: a sulfonylimide-based anion; a sulfonate-based anion; a hexafluorophosphate anion; a bis(trifluoromethylsulfonyl)imide anion; an imidodisulfuryl fluoride anion; and an iodine anion.

In the epoxy resin composition according to another embodiment of the present invention, it is preferred that (D) the ionic compound be an ionic liquid.

In the epoxy resin composition according to another embodiment of the present invention, it is preferred that (D) the ionic compound have a reactive group.

In the epoxy resin composition according to another embodiment of the present invention, it is preferred that a content ratio of (D) the ionic compound be from 0.0001 mass % to 3.1 mass % with respect to an entire amount of the epoxy resin composition.

In the epoxy resin composition according to another embodiment of the present invention, it is preferred that a content ratio of (D) the ionic compound be 0.001 mass % or more and 1.2 mass % or less with respect to an entire amount of the epoxy resin composition.

In the epoxy resin composition according to another embodiment of the present invention, it is preferred that (D) the ionic compound contain at least one selected from the group consisting of: (D-1) 1-butyl-1-methylpyrrolidinium bis(trifluoromethylsulfonyl)imide; (D-2) tributyldodecylphosphonium bis(trifluoromethanesulfonyl)imide; (D-3) 1-hexyl-4-methylpyridinium bis(trifluoromethanesulfonyl)imide; (D-4) trimethylpropylammonium bis(trifluoromethanesulfonyl)imide; (D-5) 4-(2-ethoxyethyl)-4-methylmorpholinium bis(trifluoromethanesulfonyl)imide; (D-6) methyltrioctylammonium bis(trifluoromethanesulfonyl)imide; (D-7) tributylmethylammonium bis(trifluoromethanesulfonyl)imide; (D-8) 1-butyl-3-dodecylimidazolium bis(trifluoromethanesulfonyl)imide; (D-9) methyltrioctylammonium tosylate; (D-10) tributyldodecylphosphonium tosylate; (D-11) tributyldodecylphosphonium dodecylbenzenesulfonate; (D-12) N-oleyl-N,N-di(2-hydroxyethyl)-N-methylammonium bis(trifluoromethanesulfonyl)imide; (D-13) tributyl[3-(trimethoxysilyl)propyl]phosphonium 1,1,1-trifluoro-N-[(trifluoromethyl)sulfonyl]methanesulfonamide; (D-14) methyltrioctylammonium imidodisulfuryl fluoride; (D-15) tetrabutylammonium hexafluorophosphate; and (D-16) methyltrioctylammonium hexafluorophosphate.

In the epoxy resin composition according to another embodiment of the present invention, it is preferred that (A) the epoxy resin contain a liquid epoxy resin.

In the epoxy resin composition according to another embodiment of the present invention, it is preferred that (A) the epoxy resin contain at least one selected from the group consisting of: a bisphenol F-type epoxy resin; a bisphenol A-type epoxy resin; a biphenyl-type epoxy resin; an aminophenol-type epoxy resin; and a naphthalene-type epoxy resin.

In the epoxy resin composition according to another embodiment of the present invention, it is preferred that the epoxy resin composition include (C1) a large-diameter filler having an average particle diameter of 0.2 μm or more as (C) the filler, and a content ratio of (C1) the large-diameter filler be from 35 mass % to 70 mass % with respect to an entire amount of the epoxy resin composition.

In the epoxy resin composition according to another embodiment of the present invention, it is preferred that the average particle diameter of (C1) the large-diameter filler be from 0.2 μm to 3.0 μm.

In the epoxy resin composition according to another embodiment of the present invention, it is preferred that the epoxy resin composition include (C2) a small-diameter filler having an average particle diameter of less than 0.2 μm as (C) the filler, and the average particle diameter of (C2) the small-diameter filler be from 5 nm to 120 nm.

It is preferred that the epoxy resin composition according to another embodiment of the present invention further include (E) an additive, wherein the epoxy resin composition includes core-shell type rubber particles as (E) the additive.

It is preferred that the epoxy resin composition according to another embodiment of the present invention be used as a sealing material for a semiconductor device.

According to one embodiment of the present invention, there is provided a semiconductor device, including: a substrate; a semiconductor element arranged on the substrate; and a cured product of the epoxy resin composition of the present invention sealing a gap between the semiconductor element and the substrate.

According to one embodiment of the present invention, there is provided a method of producing a semiconductor device, including the steps of: filling a gap between a substrate and a semiconductor element arranged on the substrate with the epoxy resin composition of the present invention; and curing the epoxy resin composition.

### Advantageous Effects of Invention

According to the present invention, the epoxy resin composition having novel composition, the composition being capable of suppressing the bias of the distribution of a filler dispersed in a sealing material (cured product) covering an electrode connection portion, the semiconductor device produced by using the composition, and the method of producing the semiconductor device can be provided.

### BRIEF DESCRIPTION OF THE DRAWINGS

FIG. 1 is a sectional view for showing an example of the sectional structure of a semiconductor device.

### DETAILED DESCRIPTION

### Epoxy Resin Composition

An epoxy resin composition of this embodiment includes: (A) an epoxy resin; (B) a curing agent; (C) a filler; and (D) an ionic compound in which at least one of a cation or an anion is organic matter. Accordingly, when, at the time of flip-chip mounting, an epoxy resin composition is filled into a space between an electronic element such as a semiconductor element and a substrate, and is then heated and cured, the use of the epoxy resin composition of this embodiment as the epoxy resin composition can suppress the bias of the distribution of a filler dispersed in a sealing material (cured product) covering an electrode connection portion. Accordingly, a semiconductor device or any other electronic device having high connection reliability is easily obtained. Although details about the reason why such effect is obtained are unclear, the inventors of the present invention have assumed the reason to be as described below.

First, a potential difference occurs at or near the connection interface of an electrode connection portion between an element-side electrode and a substrate-side electrode in which a metal material for forming an element-side electrode connection surface and a metal material for forming a substrate-side electrode connection surface are different from each other. Accordingly, in a related-art epoxy resin composition that does not use any ionic compound, a charged filler in the epoxy resin composition filled into the periphery of the electrode connection portion is liable to move toward one of the semiconductor element or the substrate owing to electrophoresis. Probably as a result of the foregoing, the bias of the distribution of the filler dispersed in the sealing material (cured product) covering the electrode connection portion is liable to occur.

However, when the epoxy resin composition of this embodiment is used, the charge of the filler is released to the outside through the ionic compound having conductivity. As a result, the filler reduced in charge quantity hardly moves toward each of the semiconductor element and the substrate. Probably as a result of the foregoing, the bias of the distribution of the filler dispersed in the sealing material (cured product) covering the electrode connection portion can be suppressed.

As described above, it has been known that in flip-chip mounting including using a metal pillar as an electrode member, the separation and aggregation of a filler in an epoxy resin composition, and a phenomenon in which the distribution of the filler in a sealing material is biased occur. Accordingly, the epoxy resin composition of this embodiment is particularly suitably used as an underfill to be utilized at the time of the production of a semiconductor device by the flip-chip mounting including using the metal pillar as an electrode member. However, when phenomena substantially the same as those described above occur at the time of the production of various electronic devices such as a semiconductor device through use of a related-art general epoxy resin composition, the epoxy resin composition of this embodiment may of course be used at the time of the production of a semiconductor device to be produced by a mounting method except the flip-chip mounting including using the metal pillar or of various electronic devices except a semiconductor device. Next, details about the respective components for forming the epoxy resin composition of this embodiment are described below.

### (A) Epoxy Resin

The epoxy resin to be used in the epoxy resin composition of this embodiment is not particularly limited as long as the resin is any one of various epoxy resins to be generally used for sealing semiconductors. However, from the viewpoints of viscosity and injectability, a liquid epoxy resin is suitably used. In addition, only one kind of epoxy resin may be used as the epoxy resin to be blended into the epoxy resin composition, or two or more kinds of epoxy resins may be used in combination. The number of epoxy groups in (one molecule of) the epoxy resin, which only needs to be 1 or more, is preferably 2 or more in ordinary cases. Although the upper limit value of the number of epoxy groups is not particularly limited, the upper limit value is preferably 5 or less in ordinary cases. The epoxy resin may be any one of various epoxy resins to be generally used for sealing semiconductors, and is not particularly limited.

Specific examples of the epoxy resin typically include an aliphatic epoxy resin and an aromatic epoxy resin. Of those, an aromatic epoxy resin is preferred. Examples of the aromatic epoxy resin include, but not limited to: bisphenol A-type epoxy resins such as p-glycidyloxyphenyldimethyltrisbisphenol A diglycidyl ether; bisphenol F-type epoxy resins; novolac-type epoxy resins; fluorene-type epoxy resins; biphenyl aralkyl epoxy resins; diepoxy resins, such as p-tert-butyl phenyl glycidyl ether and 1,4-phenyldimethanol diglycidyl ether; biphenyl-type epoxy resins such as 3,3′,5,5′-tetramethyl-4,4′-diglycidyloxybiphenyl; aminophenol-type epoxy resins, such as diglycidylaniline, diglycidyltoluidine, triglycidyl-p-aminophenol, and tetraglycidyl-m-xylylenediamine; naphthalene-type epoxy resins; and epoxy resins each having a plant-derived skeleton.

Of those, a bisphenol F-type epoxy resin, a bisphenol A-type epoxy resin, a biphenyl-type epoxy resin, an aminophenol-type epoxy resin, and a naphthalene-type epoxy resin are suitable.

### (B) Curing Agent

The curing agent to be used in the epoxy resin composition of this embodiment only needs to be any one of various curing agents to be generally used, and is hence not particularly limited. The blending amount of the curing agent is preferably such an amount that the stoichiometric equivalent ratio (curing agent equivalent/epoxy group equivalent) thereof to the epoxy resin is from 0.6 to 1.5, more preferably such an amount that the ratio is from 0.7 to 1.2.

Examples of the curing agent include an amine-based curing agent, an acid anhydride-based curing agent, and a phenol-based curing agent. In addition, only one kind of curing agent may be used as the curing agent to be blended into the epoxy resin composition, or two or more kinds of curing agents may be used in combination.

Specific examples of the amine-based curing agent include: aliphatic polyamines, such as triethylenetetramine, tetraethylenepentamine, m-xylylenediamine, trimethylhexamethylenediamine, and 2-methylpentamethylenediamine; alicyclic polyamines, such as isophoronediamine, 1,3-bisaminomethylcyclohexane, bis(4-aminocyclohexyl)methane, norbornenediamine, and 1,2-diaminocyclohexane; piperazine-type polyamines, such as N-aminoethylpiperazine and 1,4-bis(2-amino-2-methylpropyl)piperazine; and aromatic polyamines, such as diethyltoluenediamine, dimethylthiotoluenediamine, 4,4′-diamino-3,3′-diethyldiphenylmethane, bis(methylthio)toluenediamine, diaminodiphenylmethane, m-phenylenediamine, diaminodiphenylsulfone, trimethylene bis(4-aminobenzoate), and polytetramethyleneoxide-di-p-aminobenzoate. In addition, commercial products are, for example, EPICURE-W and EPICURE-Z (Yuka Shell Epoxy K.K., product names), jERCURE (trademark)-W and jERCURE (trademark)-Z (Mitsubishi Chemical Corporation, product names), KAYAHARD A-A, KAYAHARD A-B, and KAYAHARD A-S (Nippon Kayaku Co., Ltd., product names), TOHTO AMINE HM-205 (Nippon Steel & Sumikin Chemical Co., Ltd., product name), ADEKA HARDENER EH-101 (ADEKA Corporation, product name), Epomic Q-640 and Epomic Q-643 (Mitsui Chemicals, Inc., product names), DETDA80 (Lonza K. K., product name), and TOHTO AMINE HM-205 (Nippon Steel & Sumikin Chemical Co., Ltd., product name).

Specific examples of the acid anhydride-based curing agent include: alkylated tetrahydrophthalic anhydrides, such as methyltetrahydrophthalic anhydride, methylhexahydrophthalic anhydride, and methyltetrahydrophthalic anhydride; hexahydrophthalic anhydride; methyl himic anhydride; succinic anhydride substituted with an alkenyl group; methyl nadic anhydride; and glutaric anhydride.

The phenol-based curing agent refers to a whole category of monomers, oligomers, and polymers each having a phenolic hydroxy group, and specific examples thereof include a phenol novolac resin and an alkylated product or an allylated product thereof, a cresol novolac resin, a phenol aralkyl (including phenylene and biphenylene skeletons) resin, a naphthol aralkyl resin, a triphenol methane resin, and a dicyclopentadiene-type phenol resin.

### (C) Filler

The filler is blended into the epoxy resin composition of this embodiment from the viewpoint of, for example, reducing mainly the linear expansion coefficient of a sealed site (cured product) to improve the thermal cycle resistance thereof or to improve the moisture resistance thereof. The filler is not particularly limited as long as the filler has a reducing effect on the linear expansion coefficient of the cured product, and hence a known filler may be appropriately utilized. For example, an alumina filler or a silica filler may be utilized. In addition, the filler may be subjected to surface treatment with a silane coupling agent or the like.

Although the particle diameter, blending amount, and the like of the filler to be blended into the epoxy resin composition are not particularly limited, at least a filler having an average particle diameter of 0.2 μm or more ((C1) a large-diameter filler) is preferably blended into the epoxy resin composition of this embodiment in ordinary cases. The average particle diameter of the large-diameter filler is not particularly limited as long as the average particle diameter is 0.2 μm or more. However, from a practical viewpoint, the average particle diameter is suitably from 0.2 μm to 3.0 μm. In addition, the content ratio of the large-diameter filler to be blended into the epoxy resin composition is preferably from 35 mass % to 70 mass %, more preferably from 40 mass % to 69 mass %, still more preferably from 45 mass % to 68 mass % with respect to the entire amount of the epoxy resin composition. When the content ratio of the large-diameter filler is set to 35 mass % or more, the linear expansion coefficient of the cured product becomes smaller, and hence it becomes easier to improve the thermal cycle resistance. When the content ratio is set to 70 mass % or less, the viscosity of the epoxy resin composition becomes lower, and hence it becomes easier to improve the injectability of the epoxy resin composition.

In addition, it is more preferred that a filler having an average particle diameter of less than 0.2 μm (200 nm) ((C2) a small-diameter filler) be further blended into the epoxy resin composition of this embodiment in combination with the large-diameter filler. The blending of the combination of the large-diameter filler and the small-diameter filler into the epoxy resin composition further facilitates the suppression of the bias of the distribution of the filler dispersed in the sealing material (cured product) covering the electrode connection portion. In addition to the foregoing, the blending facilitates an increase in filling amount of the filler with respect to the epoxy resin composition. The average particle diameter of the small-diameter filler is not particularly limited as long as the average particle diameter is less than 0.2 μm. However, from a practical viewpoint, the average particle diameter is suitably from 5 nm to 120 nm.

The shape of the large-diameter filler is not particularly limited, and may be any one of, for example, a spherical shape, an indefinite shape, or a flaky shape. The shape of the small-diameter filler is also not particularly limited, and may be any one of, for example, a spherical shape, an indefinite shape, or a flaky shape. The shape of a small-diameter filler produced by wet synthesis is a spherical shape. In the description of the present application, the average particle diameter of the large-diameter filler means the value of a volume-average particle diameter D50 (particle diameter at which the cumulative ratio of particles from the small particle diameters of a particle size distribution becomes 50%) measured with a laser diffraction method particle size distribution-measuring device (LS 13 320 manufactured by Beckman Coulter, Inc.). The measurement was performed as follows: a sample for measurement was prepared by blending 5 mg of the filler into 50 mg of a dispersant and dispersing the filler therein with an ultrasonic disperser for 10 minutes; and its average particle diameter was measured by using pure water as a solvent under the conditions of a flow rate of 50 ml/sec, a measurement time of 90 seconds, and a solvent refractive index of 1.333. In addition, the average particle diameter of the small-diameter filler is a value measured on the basis of an image of the filler taken with a field emission scanning electron microscope (FE-SEM) (JSM-7500 manufactured by JEOL Ltd.) at a magnification of from 100,000 to 1,000,000. Herein, the particle diameter of the filler means a value obtained by: subjecting the image to binarization processing with image processing software (Win ROOF); separating the filler portion as a circle through use of the circular shape-separating function of the software; and measuring the diameter of the circle.

### (D) Ionic Compound

The following ionic compound is blended into the epoxy resin composition of this embodiment: the ionic compound includes the cation and the anion; and at least one of the cation or the anion is organic matter. A known ionic compound may be used as the ionic compound. At least part of the ionic compound is particularly preferably soluble in the epoxy resin in the use temperature region of the epoxy resin composition of this embodiment. The term “soluble” means that the dissolution amount of the ionic compound in the epoxy resin composition at room temperature (25° C.) is 0.0005 g or more with respect to 100 g of the epoxy resin in the epoxy resin composition. The dissolution amount of the ionic compound with respect to 100 g of the epoxy resin is preferably 0.001 g or more, more preferably 0.003 g or more. In addition, the melting point of the ionic compound, which is not particularly limited, is preferably 250° C. or less, more preferably 100° C. or less, still more preferably less than normal temperature (25° C.). The ionic compound having a melting point of 100° C. or less is known as a so-called “ionic liquid.” In addition, although the lower limit value of the melting point of the ionic compound is not particularly limited, the lower limit value is suitably −100° C. or more in practical use.

The ionic compound preferably has a reactive group in a molecule thereof. Examples of such reactive group include a trimethylsilyl group, a hydroxy group, a carboxyl group, an aldehyde group, a hydroxy group, a carboxy group, a nitro group, an amino group, a sulfo group, and a methacrylic group. When the ionic compound having a reactive group is blended into the epoxy resin composition, at the time of the curing of the epoxy resin composition, the ionic compound reacts with a resin matrix for forming the cured body to be fixed in the cured body. Accordingly, it becomes easy to suppress various inconveniences caused by the contamination of the vicinity of a sealing material (cured body) for a semiconductor device by the ionic compound due to the exudation of the ionic compound from the sealing material. In addition, it becomes also easy to increase the amount of the ionic compound to be blended into the epoxy resin composition because it becomes easy to suppress the exudation of the ionic compound from the cured body. Accordingly, the degree of freedom in composition design of the epoxy resin composition of this embodiment can be further improved so as to be capable of corresponding to various needs. When the ionic compound contains a chain cation molecule and/or a chain anion molecule, the reactive group is preferably arranged at a terminal of a chain molecule for forming the ionic compound. Thus, it becomes easier to cause the ionic compound to react with the resin matrix for forming the cured body at the time of the curing of the epoxy resin composition to fix the compound in the cured body. In addition, various compounds may be utilized as the cation and the anion for forming the ionic compound as long as the compounds can form the ionic compound. However, a cation and an anion each of which is free of any trifluoromethyl group are suitably utilized for the purpose of reducing the release of a perfluoroalkyl compound and a polyfluoroalkyl compound, and salts thereof (PFAS) to an environment. In this case, an ionic compound in which the cation and the anion each include a molecule free of any trifluoromethyl group is more suitable.

As the ionic compound, for example, a pyridinium-based ionic compound, an imidazolium-based ionic compound, an ammonium-based ionic compound, a phosphonium-based ionic compound, a pyrrolidinium-based ionic compound, a piperidinium-based ionic compound, a sulfonate-based ionic compound, and an iodine-based ionic compound may be used. In addition, when a suitable combination of a cation and an anion is focused on, it is preferred that the ionic compound contain <i>at least one kind of cation selected from the group consisting of: a pyridinium-based cation; an imidazolium-based cation; an ammonium-based cation; a pyrrolidinium-based cation; a piperidinium-based cation; and a phosphonium-based cation, and <ii>at least one kind of anion selected from the group consisting of: a sulfonylimide-based anion; a sulfonate-based anion; a hexafluorophosphate anion; a bis(trifluoromethylsulfonyl)imide anion; an imidodisulfuryl fluoride anion; and an iodine anion.

Examples of the pyridinium-based ionic compound may include 1-hexyl-4-methylpyridinium bis(trifluoromethanesulfonyl)imide, 1-butyl-3-methylpyridinium bis(trifluoromethylsulfonyl)imide, 1-butyl-4-methylpyridinium bromide, 1-butyl-4-methylpyridinium chloride, 1-butyl-4-methylpyridinium hexafluorophosphate, 1-butyl-4-methylpyridinium iodide, 4-methyl-N-butylpyridinium tetrafluoroborate, 1-butylpyridinium bromide, 1-(3-cyanopropyl)pyridinium chloride, 1-ethylpyridinium tetrafluoroborate, and 3-methyl-1-propylpyridinium bis(trifluoromethylsulfonyl)imide.

Examples of the imidazolium-based ionic compound include 1-butyl-3-dodecylimidazolium bis(trifluoromethanesulfonyl)imide, 1-allyl-3-methylimidazolium bis(trifluoromethylsulfonyl)imide, 1-allyl-3-methylimidazolium bromide, 1-allyl-3-methylimidazolium chloride, 1-allyl-3-methylimidazolium dicyanamide, 1-allyl-3-methylimidazolium iodide, 1-benzyl-3-methylimidazolium chloride, 1-benzyl-3-methylimidazolium hexafluorophosphate, 1-benzyl-3-methylimidazolium tetrafluoroborate, 1,3-bis(cyanomethyl)imidazolium bis(trifluoromethylsulfonyl)imide, 1,3-bis(cyanomethyl)imidazolium chloride, 1,3-bis(3-cyanopropyl)imidazolium bis(trifluoromethylsulfonyl)imide, 1,3-bis(3-cyanopropyl)imidazolium chloride, 1-butyl-2,3-dimethylimidazolium chloride, 1-butyl-2,3-dimethylimidazolium hexafluorophosphate, 1-butyl-2,3-dimethylimidazolium tetrafluoroborate, 4-(3-butyl-1-imidazolio)-1-butanesulfonate, 1-butyl-3-methylimidazolium acetate, 1-butyl-3-methylimidazolium bis(trifluoromethylsulfonyl)imide, 1-butyl-3-methylimidazolium bromide, 1-butyl-3-methylimidazolium chloride, 1-butyl-3-methylimidazolium dibutyl phosphate, 1-butyl-3-methylimidazolium dicyanamide, 1-butyl-3-methylimidazolium hexafluoroantimonate, and 1-butyl-3-methylimidazolium hexafluorophosphate. A commercial product may be, for example, 356-41191.

Examples of the ammonium-based ionic compound include tributylmethylammonium bis(trifluoromethanesulfonyl)imide, trimethylpropylammonium bis(trifluoromethanesulfonyl)imide, 4-(2-ethoxyethyl)-4-methylmorpholinium bis(trifluoromethanesulfonyl)imide, butyltrimethylammonium bis(trifluoromethanesulfonyl)imide, ethyldimethylpropylammonium bis(trifluoromethylsulfonyl)imide, 2-hydroxyethyltrimethylammonium lactate, methyl-trioctylammonium bis(trifluoromethylsulfonyl)imide, methyltrioctylammonium thiosalicylate, tetrabutylammonium nonafluorobutanesulfonate, tetraethylammonium tri fluoromethanesulfonate, tetraheptylammonium chloride, tributylmethylammonium dibutyl phosphate, tributylmethylammonium methyl sulfate, triethylmethylammonium dibutyl phosphate, tris(2-hydroxyethyl)methylammonium methyl sulfate, trioctylmethylammonium thiocyanate, trioctylmethylammonium p-toluenesulfonate, N,N-diethyl-N-(2-methoxyethyl)-N-methylammonium methoxyacetate, tetrabutylammonium acetate, tetraethylammonium tri fluoromethanesulfonate, tributylmethylammonium dibutyl phosphate, methyltrioctylammonium tosylate, N-oleyl-N,N-di(2-hydroxyethyl)-N-methylammonium bis(trifluoromethanesulfonyl)imide, methyltrioctylammonium imidodisulfuryl fluoride, and tetrabutylammonium hexafluorophosphate. Commercial products may be, for example, T1745, IL2-3, T2694, ILA2-9, ILA48-32, and 669962.

Examples of the phosphonium-based ionic compound include tributyldodecylphosphonium bis(trifluoromethanesulfonyl)imide, tetrabutylphosphonium methanesulfonate, tributylmethylphosphonium dibutyl phosphate, tributylmethylphosphonium triethylmethylphosphonium methyl sulfate, dibutyl phosphate, trihexyltetradecylphosphonium bis(trifluoromethylsulfonyl)amide, tributyldodecylphosphonium p-toluenesulfonate, trihexyltetradecylphosphonium bis(2,4,4-trimethylpentyl)phosphinate, trihexyltetradecylphosphonium bromide, trihexyltetradecylphosphonium chloride, trihexyltetradecylphosphonium decanoate, trihexyltetradecylphosphonium dicyanamide, 3-(triphenylphosphonio)propane-1-sulfonate, 3-(triphenylphosphonio)propane-1-sulfonic acid tosylate, 1-butanaminium, N,N-dibutyl-N-methyl, dibutyl phosphate, tributyldodecylphosphonium tosylate, tributyldodecylphosphonium dodecylbenzenesulfonate, and tributyl[3-(trimethoxysilyl)propyl]phosphonium 1,1,1-trifluoro-N-[(trifluoromethyl)sulfonyl]methanesulfonamide. A commercial product may be, for example, ILAP3-3.

Examples of the pyrrolidinium-based ionic compound include 1-butyl-1-methylpyrrolidinium bis(trifluoromethylsulfonyl)imide, 1-butyl-1-methylpyrrolidinium bromide, 1-butyl-1-methylpyrrolidinium chloride, 1-butyl-1-methylpyrrolidinium dicyanamide, 1-butyl-1-methylpyrrolidinium hexafluorophosphate, 1-butyl-1-methylpyrrolidinium iodide, 1-butyl-1-methylpyrrolidinium tetrafluoroborate, 1-butyl-1-methylpyrrolidinium trifluoromethanesulfonate, 1-ethyl-1-methylpyrrolidinium bis(trifluoromethylsulfonyl)imide, 1-ethyl-1-methylpyrrolidinium bromide, 1-ethyl-1-methylpyrrolidinium hexafluorophosphate, 1-ethyl-1-methylpyrrolidinium tetrafluoroborate, and 1-butyl-1-methylpyrrolidinium tetrafluoroborate. A commercial product may be, for example, 322-87291.

Examples of the piperidinium-based ionic compound may include 1-methyl-1-propylpiperidinium bis(trifluoromethylsulfonyl)imide and 1-butyl-1-methylpiperidinium bis(trifluoromethylsulfonyl)imide.

Examples of the sulfonate-based ionic compound may include methyltrioctylammonium tosylate, tributyldodecylphosphonium tosylate, and tributyldodecylphosphonium dodecylbenzenesulfonate.

Examples of the iodine-based ionic compound may include 1,3-dimethylimidazolium iodide, 1-ethyl-3-methylimidazolium iodide, 1-ethyl-3-propylimidazolium iodide, 1-butyl-3-methylimidazolium iodide, 1-hexyl-3-methylimidazolium iodide, 1-allyl-3-methylimidazolium iodide, 1-allyl-3-ethylimidazolium iodide, and 1,2-dimethyl-3-propylimidazolium iodide.

Of those, as the ionic compound, (D-1) 1-butyl-1-methylpyrrolidinium bis(trifluoromethylsulfonyl)imide, (D-2) tributyldodecylphosphonium bis(trifluoromethanesulfonyl)imide, (D-3) 1-hexyl-4-methylpyridinium bis(trifluoromethanesulfonyl)imide, (D-4) trimethylpropylammonium bis(trifluoromethanesulfonyl)imide, (D-5) 4-(2-ethoxyethyl)-4-methylmorpholinium bis(trifluoromethanesulfonyl)imide, (D-6) methyltrioctylammonium bis(trifluoromethanesulfonyl)imide, (D-7) tributylmethylammonium bis(trifluoromethanesulfonyl)imide, (D-8) 1-butyl-3-dodecylimidazolium bis(trifluoromethanesulfonyl)imide, (D-9) methyltrioctylammonium tosylate, (D-10) tributyldodecylphosphonium tosylate, (D-11) tributyldodecylphosphonium dodecylbenzenesulfonate, (D-12) N-oleyl-N,N-di(2-hydroxyethyl)-N-methylammonium bis(trifluoromethanesulfonyl)imide, (D-13) tributyl[3-(trimethoxysilyl)propyl]phosphonium 1,1,1-trifluoro-N-[(trifluoromethyl)sulfonyl]methanesulfonamide, (D-14) methyltrioctylammonium imidodisulfuryl fluoride, (D-15) tetrabutylammonium hexafluorophosphate, and (D-16) methyltrioctylammonium hexafluorophosphate are preferred. In addition, only one kind of ionic compound may be used as the ionic compound to be blended into the epoxy resin composition, or two or more kinds of ionic compounds may be used in combination.

Although the content ratio of the ionic compound with respect to the entire amount of the epoxy resin composition is not particularly limited, the content ratio is preferably from 0.0001 mass % (1 ppm) to 3.1 mass % (31,000 ppm). When the content ratio of the ionic compound is set to 0.0001 mass % (1 ppm) or more, it becomes easy to more reliably suppress the bias of the distribution of the filler dispersed in the sealing material (cured product) covering the electrode connection portion. In addition, when the content ratio of the ionic compound is set to 3.1 mass % (31,000 ppm) or less, it becomes easy to suppress various inconveniences caused by the contamination of the vicinity of the sealing material (cured body) for the semiconductor device by the ionic compound due to the exudation of the ionic compound from the sealing material. The lower limit value of the content ratio of the ionic compound is more preferably 0.001 mass % (10 ppm) or more, still more preferably 0.003 mass % (30 ppm) or more, still more preferably 0.005 mass % (50 ppm) or more. In addition, the upper limit value of the content ratio of the ionic compound is more preferably 3.0 mass % (30,000 ppm) or less, still more preferably 2.0 mass % (20,000 ppm) or less, still more preferably 1.2 mass % (12,000 ppm) or less, still more preferably 1.0 mass % (10,000 ppm) or less, still more preferably 0.5 mass % (5,000 ppm) or less, still more preferably 0.1 mass % (1,000 ppm) or less, still more preferably 0.05 mass % (500 ppm) or less.

In addition, from the same viewpoint, the content of the ionic compound with respect to 100 parts by mass of the epoxy resin containing 2 or more epoxy groups is preferably from 0.002 part by mass to 11 parts by mass. Further, from the viewpoint of further improving the injectability of the epoxy resin composition, the content of the ionic compound is more preferably more than 0.8 part by mass and 11 parts by mass or less, still more preferably from 1 part by mass to 11 parts by mass.

In addition, the total amount of (A) the epoxy resin and (D) the ionic compound with respect to the entire amount of all organic components in the epoxy resin composition is preferably 85 mass % or less, more preferably 82 mass % or less. When the total amount of (A) the epoxy resin and (D) the ionic compound with respect to the entire amount of all the organic components is set to 85 mass % or less, the occurrence of a curing failure at the time of the heating of the epoxy resin composition can be suppressed. Although the lower limit value of the total amount of (A) the epoxy resin and (D) the ionic compound with respect to the entire amount of all the organic components is not particularly limited, the lower limit value is preferably 40 mass % or more, more preferably 50 mass % or more in practical use.

### (E) Additive

In addition to the components (A) to (D), various additives may each be further blended into the epoxy resin composition of this embodiment as required. Although the additives are not particularly limited, examples thereof include core-shell type rubber particles, a curing accelerator, a silane coupling agent, a viscosity depressant, an ion-trapping agent, a leveling agent, an antioxidant, a defoaming agent, a flame retardant, a colorant, and a reactive diluent. The kinds and blending amounts of those additives are the same as those of an ordinary method. Details about some of the additives are described below.

The core-shell type rubber particles to be used as an additive impart injectability to the epoxy resin composition to suppress the peeling and migration of the epoxy resin composition after its curing. Rubber particles each having a core-shell structure to be subjected to master batch treatment are, for example, the following rubber particles: rubber particles each formed of the combination of polybutadiene serving as a core and an acrylic copolymer serving as a shell; or rubber particles each formed of the combination of a silicone resin serving as a core and an acrylic copolymer or the like serving as a shell. Of those, rubber particles each formed of the combination of polybutadiene serving as a core and an acrylic copolymer serving as a shell are preferred because the particles can reduce the shrinkage stress of the epoxy resin composition by virtue of their low elastic modulus in the use temperature region of the epoxy resin composition. The master batch treatment on the rubber particles each having a core-shell structure may be performed with an epoxy resin or a curing agent such as an acid anhydride, and an epoxy resin, in particular, a bisphenol-type epoxy resin is preferred from the viewpoint of the presence or absence of adverse effects on the storage stability and humidity of the composition. Examples of the bisphenol-type epoxy resin include a bisphenol A-type epoxy resin and a bisphenol F-type epoxy resin. Of those, a bisphenol F-type epoxy resin is more preferred.

The curing accelerator to be used as an additive imparts an appropriate curing rate to the epoxy resin composition. Examples of the curing accelerator include 2-methylimidazole, 2-undecylimidazole, 2-heptadecylimidazole, 2-ethyl-4-methylimidazole, 2-phenylimidazole, and 2-phenyl-4-methylimidazole. Commercial products are, for example, 2-phenyl-4-methylimidazole (product name: 2P4MZ) manufactured by Shikoku Chemicals Corporation and 2,4-diamino-6-[2′-methylimidazolyl-(1′)]-ethyl-s-triazine (product name: 2MZA) manufactured by Shikoku Chemicals Corporation. The curing accelerators may be used alone or in combination thereof.

The silane coupling agent to be used as an additive imparts adhesiveness between the epoxy resin composition and a semiconductor element or a substrate. Commercial products are, for example, Z-6610, Z-6011, Z-6020, Z-6094, Z-6883, Z-6032, Z-6040, Z-6044, Z-6043, Z-6075, Z-6300, Z-6519, Z-6825, Z-6030, 2-6033, Z-6062, Z-6862, Z-6911, Z-6026, AZ-720, and Z-6050 (each of which is manufactured by Dow Corning Toray Co., Ltd.), and KBM-303, KBM-402, KBM-403, KBE-402, KBE-403, KBM-1403, KBM-502, KBM-503, KBE-502, KBE-503, KBM-5103, KBM-602, KBM-603, KBE-603, KBM-903, KBE-903, KBE-9103, KBM-573, KBM-575, KBE-585, KBM-1003, KBE-1003, KBM-802, KBM-803, KBE-846, KBE-9007, X-41-1053, X-41-1056, X-41-1059A, X-41-1805, X-41-1808, X-41-1810, KR-513, X-40-2672B, X-40-9272B, and X-40-2651 (each of which is manufactured by Shin-Etsu Chemical Co., Ltd.). The silane coupling agents may be used alone or in combination thereof.

The epoxy resin composition of this embodiment may be prepared by mixing and stirring at least the components (A) to (D), and at this time, the component (E) may be further blended as required. A method for the mixing and stirring is not particularly limited, and a known mixing and stirring method such as a roll mill may be utilized. In addition, when (A) the epoxy resin to be used as a raw material is in a solid state, the resin is preferably mixed with the other components after having been liquefied by performing heating treatment or the like before the mixing. In addition, at the time of the preparation of the epoxy resin composition, all the components serving as raw materials may be mixed at a time, or the following may be performed: some components selected from all the components serving as raw materials are mixed to prepare a primary mixture, and the primary mixture is mixed with the remaining components. For example, in the case where (C1) the large-diameter filler is used as (C) the filler, when it is difficult to uniformly disperse (C1) the large-diameter filler in (A) the epoxy resin, the following may be performed: (A) the epoxy resin and (C1) the large-diameter filler are mixed to prepare a primary mixture, and the primary mixture is mixed with the remaining respective components.

### Applications of Epoxy Resin Composition, and Semiconductor Device and Method of producing the Device

Although the epoxy resin composition of this embodiment may be utilized as a sealing material for various electronic devices such as a semiconductor device, the composition is particularly suitably utilized as a sealing material for various electronic devices such as a semiconductor device which includes an electrode connection portion surrounded by the sealing material, and in which a first metal material for forming an electrode connection surface on one side of the connection interface of the electrode connection portion and a second metal material for forming an electrode connection surface on the other side thereof are different from each other. Herein, the combination of the first metal material and the second metal material is not particularly limited as long as the combination causes a potential difference at the time of the connection of both the materials. However, the following combination is suitable: (a) the combination of the first metal material selected from the group consisting of: copper; a copper alloy; silver; a silver alloy; gold; and a gold alloy, and the second metal material selected from the group consisting of: tin; and a tin alloy; or (b) the combination of metal materials causing a potential difference comparable to or larger than that of the combination (a). When the epoxy resin composition of this embodiment is used to perform resin sealing at the time of the production of an electronic device including such electrode connection portion, the bias of the distribution of the filler dispersed in the sealing material (cured product) covering the electrode connection portion can be suppressed.

In addition, a semiconductor device of this embodiment only needs to include: a substrate; a semiconductor element arranged on the substrate; and a sealing material (a cured product of the epoxy resin composition of this embodiment) sealing a gap between the semiconductor element and the substrate. The semiconductor device includes an electrode connection portion in which the electrode connection surface of an element-side electrode arranged on the semiconductor element and the electrode connection surface of a substrate-side electrode arranged on the substrate are connected to each other, and the sealing material is arranged so as to surround the electrode connection portion. In the semiconductor device of this embodiment, it is particularly preferred that an element-side metal material for forming the electrode connection surface of the element-side electrode and a substrate-side metal material for forming the electrode connection surface of the substrate-side electrode arranged on the substrate be different from each other. A suitable combination of both the materials is the same as the suitable combination of the first metal material and the second metal material described above. Although the element-side electrode and the substrate-side electrode may each include, for example, a solder bump or a metal pillar, the element-side electrode preferably includes a metal pillar such as a copper pillar.

The semiconductor device of this embodiment is produced at least through the following steps: a step (filling step) of filling the gap between the substrate and the semiconductor element arranged on the substrate with the epoxy resin composition of this embodiment; and a step (curing step) of curing the epoxy resin composition filled into the gap. Prior to the filling step, there is typically performed a step (connecting step) of connecting the electrode connection surface of the element-side electrode and the electrode connection surface of the substrate-side electrode to each other to form the electrode connection portion under a state in which the surface of the semiconductor element having arranged thereon the element-side electrode and the surface of the substrate having arranged thereon the substrate-side electrode are caused to face each other. Accordingly, in the filling step, the epoxy resin composition is filled so as to surround the periphery of the electrode connection portion, and the epoxy resin composition surrounding the periphery of the electrode connection portion is cured in the curing step (serves as a cured product (sealing material)).

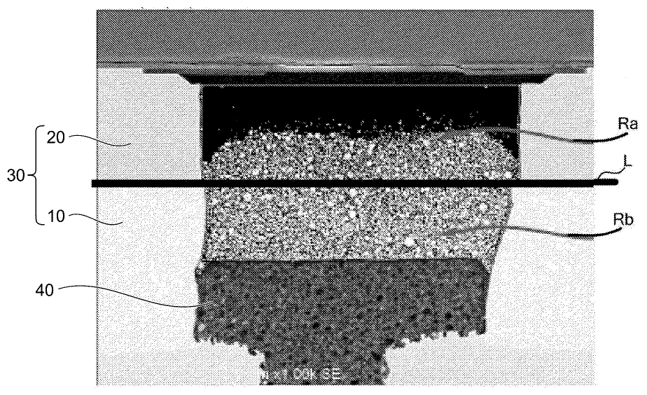

FIG. 1 is a sectional view for showing an example of the sectional structure of the semiconductor device. Specifically, a SEM image of a sectional structure near the electrode connection portion taken with a scanning electron microscope (FE-SEM) is shown. As shown in FIG. 1, a sealing material 40 that is a cured product of the epoxy resin composition filled in the filling step is arranged near an electrode connection portion 30, which includes a substrate-side electrode 10 and an element-side electrode 20 connected to the substrate-side electrode 10, so as to surround the electrode connection portion 30 (in the figure, the sealing material 40 is positioned between the pair of left and right electrode connection portions 30). In addition, in the example shown in FIG. 1, the substrate-side electrode 10 includes a solder bump formed of a tin alloy containing tin as its main component, and the element-side electrode 20 includes a copper pillar. Accordingly, the connection of both the electrodes 10 and 20 causes a potential difference. In addition, as shown in FIG. 1, the sealing material 40 includes: a filler (a relatively white portion out of the sealing material 40 in the figure); and a resin matrix (a relatively black portion out of the sealing material 40 in the figure) that is a portion except the filler. The filler and the resin matrix in the sealing material 40 can be distinguished from each other by: designating a region corresponding to the sealing material 40 in the SEM image; and subjecting the region to image processing with image processing software. Such image processing is performed by performing binarization processing with respect to the median of the brightness distribution of the designated region corresponding to the sealing material 40.

Meanwhile, a connection interface L between the electrode connection surface of the substrate-side electrode 10 and the electrode connection surface of the element-side electrode 20 is formed in the electrode connection portion 30. Herein, the region corresponding to the sealing material 40 can be divided into a semiconductor element-side region Ra and a substrate-side region Rb with respect to an extended line obtained by extending the connection interface L. In this case, the degree of the bias of the distribution of the filler dispersed in the sealing material 40 covering the electrode connection portion 30 can be quantitatively evaluated by a filler distribution index represented by the following equation (1).

Filler distribution index=100×a/b Equation (1)

Herein, in the equation (1), “a” represents the occupancy of the filler in the region Ra, and “b” represents the occupancy of the filler in the region Rb. In addition, the occupancies are values calculated on the basis of such SEM image obtained by performing the binarization processing as exemplified in FIG. 1. ImageJ available from the National Institutes of Health (NIH) was used in a series of image processing for calculating the filler distribution index.

A case in which the filler distribution index is 100 means that the filler dispersed in the sealing material 40 is distributed most uniformly (the bias of the distribution is minimum). Meanwhile, a larger degree to which the filler distribution index deviates from 100 means a larger degree of the bias of the distribution of the filler dispersed in the sealing material 40. In addition, a filler distribution index of less than 100 means that the filler is distributed while being biased toward the region Rb, and a filler distribution index of more than 100 means that the filler is distributed while being biased toward the region Ra. Which one of the region Ra and the region Rb the filler tends to be distributed while being biased toward depends on the combination of a metal material for forming the electrode connection surface of the substrate-side electrode 10 and a metal material for forming the electrode connection surface of the element-side electrode 20. In the semiconductor device of this embodiment, the filler distribution index falls preferably within the range of 100±50, more preferably within the range of 100±30, still more preferably within the range of 100±20.

### EXAMPLES

Specific examples of the present invention are described below by way of Examples. However, the present invention is not limited only to Examples described below.

### 1. Preparation of Epoxy Resin Composition

Raw materials were mixed and stirred with a roll mill so that blending ratios shown in Table 1 to Table 6 were obtained. Thus, epoxy resin compositions of Examples 1 to 51 and Comparative Example 1 were prepared. Details about the components (A) to (E) used as the raw materials are as described below.

### 2. Raw Material Components used in Preparation of Epoxy Resin Composition

### (A) Epoxy Resin

a1: YDF8170 (bisphenol F type, epoxy equivalent: 158 g/eq, number of epoxy groups: 2, manufactured by NIPPON STEEL Chemical & Material Co., Ltd.)
a2: EXA-850CRP (bisphenol A type, epoxy equivalent: 172 g/eq, number of epoxy groups: 2, manufactured by DIC Corporation)
a3: HP4032D (naphthalene type, epoxy equivalent: 140 g/eq, number of epoxy groups: 2, manufactured by DIC Corporation)
a4: jER630 (aminophenol type, epoxy equivalent: 98 g/eq, number of epoxy groups: 3, manufactured by Mitsubishi Chemical Corporation)
a5: YX7400 (biphenyl type, epoxy equivalent: 440 g/eq, number of epoxy groups: 2, manufactured by Mitsubishi Chemical Corporation)

### (B) Curing Agent

b1: HDAA (amine-based curing agent, 4,4′-diamino-3,3′-diethyldiphenylmethane, active hydrogen equivalent: 63.5 g/eq, manufactured by Nippon Kayaku Co., Ltd.)
b2: ETHACURE 100 (amine-based curing agent, diethyltrienediamine, active hydrogen equivalent: 44.6 g/eq, manufactured by Albemarle Corporation)
b3: HN5500 (acid anhydride-based curing agent, active hydrogen equivalent: 168 g/eq, manufactured by Hitachi Chemical Company, Ltd.)
b4: MEH8006 (phenol-based curing agent, active hydrogen equivalent: 135 g/eq, manufactured by Meiwa Plastic Industries, Ltd.)

### (C) Filler

### (C1) Large-diameter Filler

SE2200-SEJ (silicon dioxide subjected to surface treatment with 3-glycidoxypropyltrimethoxysilane, average particle diameter: 0.6 μm, manufactured by Admatechs)
SE1050-SE0 (silicon dioxide subjected to surface treatment with 3-glycidoxypropyltrimethoxysilane, average particle diameter: 0.3 μm, manufactured by Admatechs)
SE5200-SEE (silicon dioxide subjected to surface treatment with 3-glycidoxypropyltrimethoxysilane, average particle diameter: 2.0 μm, manufactured by Admatechs)
SE2300 (silicon dioxide without any surface treatment, average particle diameter: 0.6 μm, manufactured by Admatechs)
SE2200-SME (silicon dioxide subjected to surface treatment with 3-methacryloxypropyltrimethoxysilane, average particle diameter: 0.6 μm, manufactured by Admatechs)

Surface Treatment Agent for Large-diameter Filler
g1: 3-Glycidoxypropyltrimethoxysilane
g2: 3-Methacryloxypropyltrimethoxysilane

### (C2) Small-diameter Filler

YA010A (average particle diameter: 10 nm, manufactured by Admatechs)
YC100C (average particle diameter: 100 nm, manufactured by Admatechs)

### (D) Ionic Compound

d1: 1-Butyl-1-methylpyrrolidinium bis(trifluoromethylsulfonyl)imide (FUJIFILM Wako Pure Chemical Corporation: 027-15441, CAS No. 223437-11-4, melting point: −15° C., the following structural formula d1)

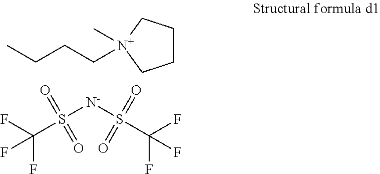

d2: Tributyldodecylphosphonium bis(trifluoromethanesulfonyl)imide (FUJIFILM Wako Pure Chemical Corporation: 205-19961, CAS No. 1002754-39-3, melting point: −16° C., the following structural formula d2)

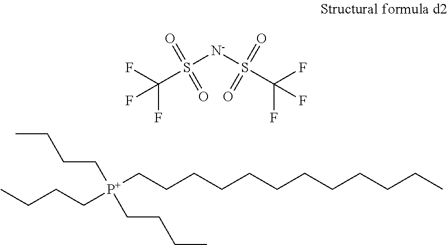 [SMILES: O=S(=O)([N-]S(=O)(=O)C(F)(F)F)C(F)(F)F ; CCCCCCCCCCCC[P+](CCCC)(CCCC)CCCC]

d3: 1-Hexyl-4-methylpyridinium bis(trifluoromethanesulfonyl)imide (FUJIFILM Wako Pure Chemical Corporation: 084-10131, CAS No. 870296-13-2, melting point: 12° C., the following structural formula d3)

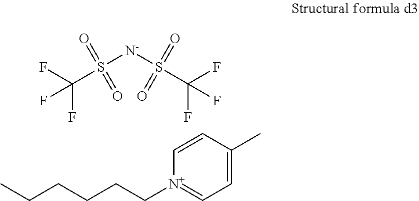

d4: Trimethylpropylammonium bis(trifluoromethanesulfonyl)imide (FUJIFILM Wako Pure Chemical Corporation: 201-19941, CAS No. 268536-05-6, melting point: 19° C., the following structural formula d4)

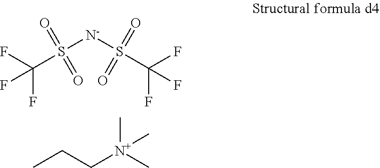

d5: 4-(2-Ethoxyethyl)-4-methylmorpholinium bis(trifluoromethanesulfonyl)imide (FUJIFILM Wako Pure Chemical Corporation: 053-09071, CAS No. 663628-48-6, melting point: unknown (however, it was recognized that the ionic compound represented by the following structural formula d5 was in a liquid state at normal temperature), the following structural formula d5)

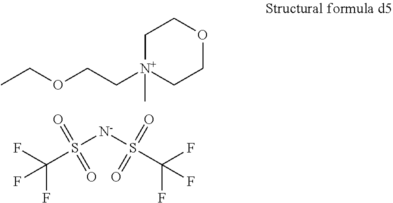

d6: Methyltrioctylammonium bis(trifluoromethanesulfonyl)imide (FUJIFILM Wako Pure Chemical Corporation: 136-17481, CAS No. 375395-33-8, melting point: −70° C., the following structural formula d6)

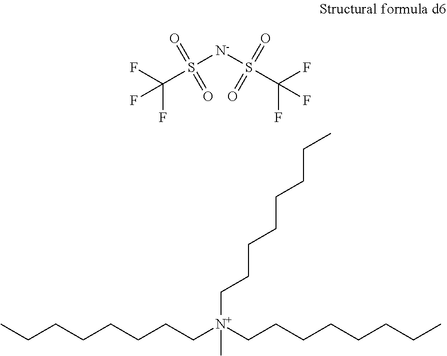 [SMILES: O=S(=O)([N-]S(=O)(=O)C(F)(F)F)C(F)(F)F ; CCCCCCCC[N+](C)(CCCCCCCC)CCCCCCCC]

d7: Tributylmethylammonium bis(trifluoromethanesulfonyl)imide (FUJIFILM Wako Pure Chemical Corporation: 352-27751, CAS No. 405514-94-5, melting point: unknown (however, it was recognized that the ionic compound represented by the following structural formula d7 was in a liquid state at normal temperature), the following structural formula d7)

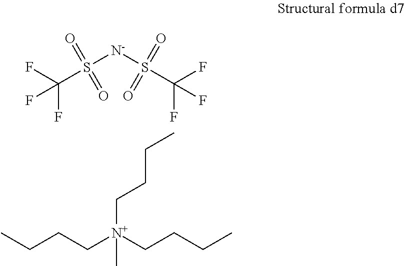

d8: 1-Butyl-3-dodecylimidazolium bis(trifluoromethanesulfonyl)imide (FUJIFILM Wako Pure Chemical Corporation: 022-18791, CAS No. 1612842-42-8, melting point: unknown (however, it was recognized that the ionic compound represented by the following structural formula d8 was in a liquid state at normal temperature), the following structural formula d8)

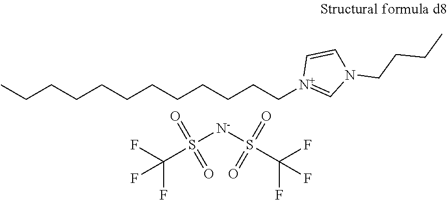 [SMILES: CCCCCCCCCCCC[n+]1ccn(CCCC)c1 ; O=S(=O)([N-]S(=O)(=O)C(F)(F)F)C(F)(F)F]

d9: Methyltrioctylammonium tosylate (melting point: 78° C., the following structural formula d9)

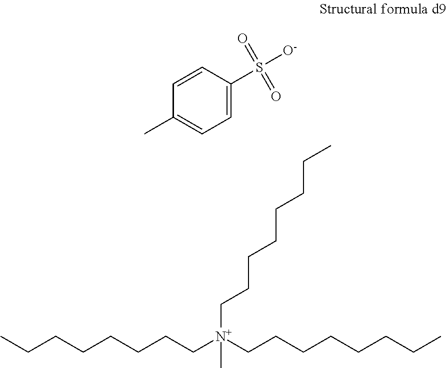 [SMILES: Cc1ccc(S(=O)(=O)[O-])cc1 ; CCCCCCCC[N+](C)(CCCCCCCC)CCCCCCCC]

d10: Tributyldodecylphosphonium tosylate (melting point: unknown (however, it was recognized that the organic salt represented by the following structural formula d10 was in a liquid state at normal temperature), the following structural formula d10)

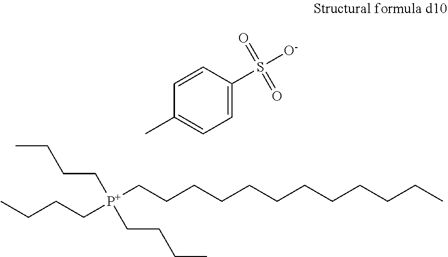 [SMILES: Cc1ccc(S(=O)(=O)[O-])cc1 ; CCCCCCCCCCCC[P+](CCCC)(CCCC)CCCC]

d11: Tributyldodecylphosphonium dodecylbenzenesulfonate (melting point: unknown (however, it was recognized that the organic salt represented by the following structural formula d11 was in a liquid state at normal temperature), the following structural formula d11)

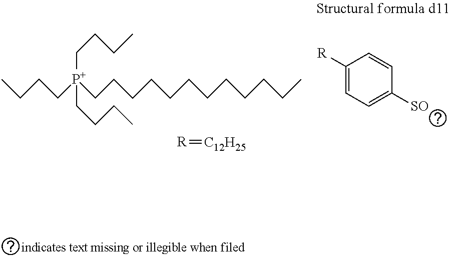

d12: N-Oleyl-N,N-di(2-hydroxyethyl)-N-methylammonium bis(trifluoromethanesulfonyl)imide (melting point: unknown (however, it was recognized that the ionic compound represented by the following structural formula d12 was in a liquid state at normal temperature), the following structural formula d12)

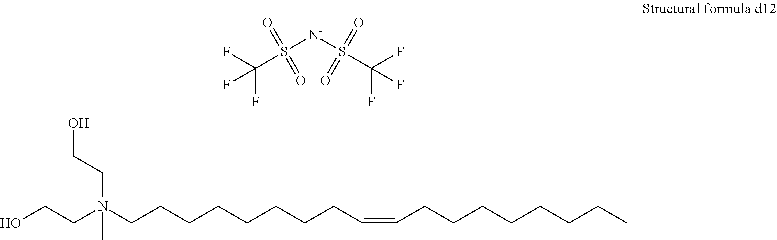 [SMILES: O=S(=O)([N-]S(=O)(=O)C(F)(F)F)C(F)(F)F ; CCCCCCCC/C=C\CCCCCCCC[N+](C)(CCO)CCO]

d13: Tributyl[3-(trimethoxysilyl)propyl]phosphonium 1,1,1-trifluoro-N-[(trifluoromethyl)sulfonyl]methanesulfonamide (melting point: unknown (however, it was recognized that the ionic compound represented by the following structural formula d13 was in a liquid state at normal temperature, the following structural formula d13)

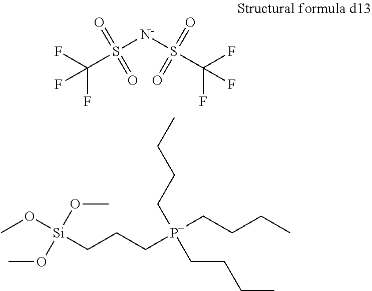 [SMILES: O=S(=O)([N-]S(=O)(=O)C(F)(F)F)C(F)(F)F ; CCCC[P+](CCCC)(CCCC)CCC[Si](OC)(OC)OC]

d14: Methyltrioctylammonium imidodisulfuryl fluoride (melting point: unknown (however, it was recognized that the ionic compound represented by the following structural formula d14 was in a liquid state at normal temperature), the following structural formula d14)

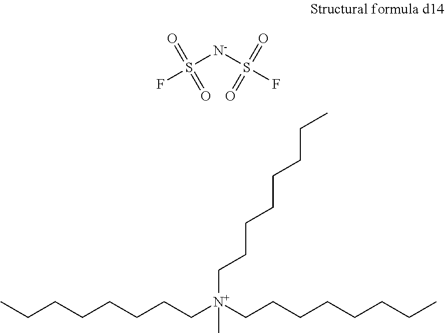 [SMILES: O=S(=O)(F)[N-]S(=O)(=O)F ; CCCCCCCC[N+](C)(CCCCCCCC)CCCCCCCC]

d15: Tetrabutylammonium hexafluorophosphate (FUJIFILM Wako Pure Chemical Corporation: 352-41372, CAS No. 3109-63-5, melting point: 242° C., the following structural formula d15)

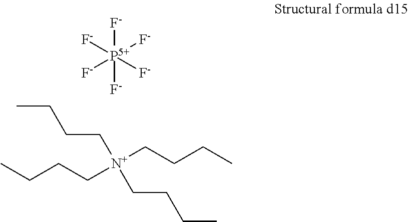

d16: Methyltrioctylammonium hexafluorophosphate (FUJIFILM Wako Pure Chemical Corporation: 133-17491, CAS No. 569652-37-5, melting point: 78° C., the following structural formula d16)

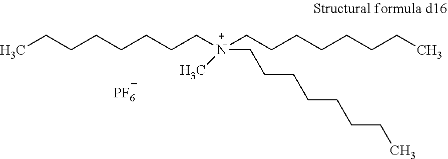

### (E) Various Additives

e1: MX-137 (core-shell type butadiene-based rubber particles, manufactured by Kaneka Corporation)
e2: MX-965 (core-shell type silicone-based rubber particles, manufactured by Kaneka Corporation)
e3: 2P4MZ (2-phenyl-4-methylimidazole, curing accelerator, manufactured by Shikoku Chemicals Corporation)
e4: KBM403 (3-glycidoxypropyltrimethoxysilane, coupling agent, manufactured by Shin-Etsu Chemical Co., Ltd.)
e5: CG1400 (dicyandiamide, curing accelerator, manufactured by Air Products and Chemicals, Inc.)
e6: TPP (Triphenylphosphine, viscosity depressant, manufactured by Hokko Chemical Industry Co., Ltd.)

### 3. Evaluation Results

The viscosity, thixotropy index, and injectability of the epoxy resin composition of each of Examples and Comparative Example, and the filler distribution index and cured product appearance of a cured product of the epoxy resin composition of each of Examples and Comparative Example were measured or evaluated by the following procedures. The results are shown in Table 1 to Table 6.

### (Viscosity)

The viscosities of the epoxy resin composition immediately after its preparation were measured with a rotating viscometer HBDV-1 (using a spindle SC4-14) manufactured by Brookfield under the conditions of: a liquid temperature of 25° C. and 50 rpm; and a liquid temperature of 25° C. and 5 rpm.

### (Thixotropy Index (T.I.))

The thixotropy index (T.I.) of the epoxy resin composition was calculated by using the two kinds of viscosities obtained in the above-mentioned viscosity measurement as the ratio of the viscosity measured at 5 rpm to the viscosity measured at 50 rpm.

### (Injectability)

A test piece was produced by fixing a glass plate instead of a semiconductor element onto an organic substrate (FR-4 substrate) while arranging a gap of 20 μm or 50 μm therebetween. Next, under a state in which the test piece was arranged on a hot plate set to a temperature of 110° C., the epoxy resin composition was applied to one end side of the glass plate. Thus, the epoxy resin composition was injected into the gap formed between the organic substrate and the glass plate. At this time, a time period required for the injection distance of the epoxy resin composition when one end side of the glass plate having applied thereto the epoxy resin composition was defined as 0 mm to reach 20 mm was measured. The procedure was performed twice, and the average of the two measured values was determined as an injection time.

### (Filler Distribution Index)

A semiconductor device was produced by flip-chip mounting through use of the epoxy resin composition. Herein, a substrate including, as the substrate-side electrode 10, a solder bump formed of a tin alloy containing tin as its main component, and a semiconductor element including the element-side electrode 20 formed of a copper pillar were used in the production of the semiconductor device. Then, a connecting step, a filling step, and a curing step were sequentially performed to produce the semiconductor device. Curing conditions in the curing step were set to 150° C. and 120 minutes.

Next, the produced semiconductor device having a chip size measuring 10 mm by 10 mm was cut with a slicer (manufactured by BUEHLER, ISOMET 4000), and its cut surface was sequentially polished with abrasive papers No. 240, No. 800, and No. 1,200. Thus, a sample for SEM observation in which the cut surface in the central portion of the semiconductor device was exposed was obtained. Then, an image of the cut surface of the sample for SEM observation was taken with a FE-SEM. Thus, such a SEM image in which the vicinity of the electrode connection portion 30 was enlarged as exemplified in FIG. 1 was obtained. Image processing was performed on the basis of the SEM image by the above-mentioned procedure to provide the occupancy “a” of the filler in the region Ra, and the occupancy “b” of the filler in the region Rb. Subsequently, those values “a” and “b” were substituted into the equation (1) to calculate the filler distribution index. A case in which the filler distribution index was within 100±50 was judged to be satisfactory.

### (Cured Product Appearance)

The epoxy resin composition was cured under the curing conditions of 150° C. and 120 minutes to provide a test piece. Next, the surface of the test piece was visually observed, and whether or not its ionic compound exuded to the surface of the test piece was observed. Evaluation criteria are as described below.
A: No exudation of the ionic compound was observed.
B: The exudation of the ionic compound was observed.

TABLE 1

| | | Abbreviation | | | | | | |
|---|---|---|---|---|---|---|---|---|
| | | or average | | | | | | |
| | | particle | Product name or | Comparative | Example | Example | Example | Example |
| | | diameter | substance name | Example 1 | 1 | 2 | 3 | 4 |
| (A) Epoxy resin | | a1 | YDF8170 | 29.4 | 28.5 | 28.5 | 28.5 | 28.5 |
| (B) Curing agent | | b1 | HDAA | 10.6 | 10.3 | 10.3 | 10.3 | 10.3 |
| (C) | (C1) Large- | 0.6 μm | SE2200SEJ | 60.0 | 60.0 | 60.0 | 60.0 | 60.0 |

| | | | | | | | |
|---|---|---|---|---|---|---|---|
| Filler | diameter filler | Surface treatment agent for | g1 | g1 | g1 | g1 | g1 |
| | | (C1) large-diameter filler | | | | | |

| (D) Ionic compound | d1 | 1-Butyl-1-methylpyrrolidinium | 1.2 | | | |
|---|---|---|---|---|---|---|
| | | bis(trifluoromethylsulfonyl)imide | | | | |
| | d2 | Tributyldodecylphosphonium | | 1.2 | | |
| | | bis(trifluoromethanesulfonyl)imide | | | | |
| | d3 | 1-Hexyl-4-methylpyridinium | | | 1.2 | |
| | | bis(trifluoromethanesulfonyl)imide | | | | |
| | d4 | Trimethylpropylammonium | | | | 1.2 |
| | | bis(trifluoromethanesulfonyl)imide | | | | |

| Equivalent ratio | | 0.9 | 0.9 | 0.9 | 0.9 | 0.9 |
|---|---|---|---|---|---|---|
| Total | | 100.0 | 100.0 | 100.0 | 100.0 | 100.0 |
| Filler distribution index | | 38 | 90 | 89 | 88 | 85 |
| Viscosity | 50 rpm (Pa · s) | 15.2 | 15.0 | 14.0 | 14.5 | 15.5 |
| | 5 rpm (Pa · s) | 10.8 | 11.0 | 11.0 | 10.0 | 11.0 |
| T.I. | | 0.7 | 0.7 | 0.8 | 0.7 | 0.7 |
| Injectability (sec.) | 50 μmGap | 147 | 150 | 135 | 140 | 150 |
| @20 mm 110° C. | 20 μmGap | 242 | 243 | 230 | 235 | 243 |

| | | | | | |
|---|---|---|---|---|---|
| Cured product appearance | A | A | A | A | A |

| | | Abbreviation | | | | | | |
|---|---|---|---|---|---|---|---|---|
| | | or average | | | | | | |
| | | particle | Product name or | Example | Example | Example | Example | Example |
| | | diameter | substance name | 5 | 6 | 7 | 8 | 9 |
| (A) Epoxy resin | | a1 | YDF8170 | 28.5 | 28.5 | 28.5 | 28.5 | 28.5 |
| (B) Curing agent | | b1 | HDAA | 10.3 | 10.3 | 10.3 | 10.3 | 10.3 |
| (C) | (C1) Large- | 0.6 μm | SE2200SEJ | 60.0 | 60.0 | 60.0 | 60.0 | 60.0 |

| | | | | | | | |
|---|---|---|---|---|---|---|---|
| Filler | diameter filler | Surface treatment agent for | g1 | g1 | g1 | g1 | g1 |
| | | (C1) large-diameter filler | | | | | |

| (D) Ionic compound | d5 | 4-(2-Ethoxyethyl)-4- | 1.2 | | | | |
|---|---|---|---|---|---|---|---|
| | | methylmorpholinium | | | | | |
| | | bis(trifluoromethylsulfonyl)imide | | | | | |
| | d6 | Methyltrioctylammonium | | 1.2 | | | 0.6 |
| | | bis(trifluoromethanesulfonyl)imide | | | | | |
| | d7 | Tributylmethylammonium | | | 1.2 | | |
| | | bis(trifluoromethanesulfonyl)imide | | | | | |
| | d8 | 1-Butyl-3-dodecylimidazolium | | | | 1.2 | |
| | | bis(trifluoromethanesulfonyl)imide | | | | | |

| Equivalent ratio | | 0.9 | 0.9 | 0.9 | 0.9 | 0.9 |
|---|---|---|---|---|---|---|
| Total | | 100.0 | 100.0 | 100.0 | 100.0 | 100.0 |
| Filler distribution index | | 86 | 86 | 87 | 89 | 90 |
| Viscosity | 50 rpm (Pa · s) | 16.0 | 15.0 | 14.5 | 16.0 | 15.0 |
| | 5 rpm (Pa · s) | 11.0 | 11.0 | 10.0 | 11.0 | 10.0 |
| T.I. | | 0.7 | 0.7 | 0.7 | 0.7 | 0.7 |
| Injectability (sec.) | 50 μmGap | 160 | 145 | 140 | 155 | 145 |
| @20 mm 110° C. | 20 μmGap | 250 | 242 | 234 | 251 | 240 |

| | | | | | |
|---|---|---|---|---|---|
| Cured product appearance | A | A | A | A | A |

TABLE 2

| | | Abbreviation | | | | | | |
|---|---|---|---|---|---|---|---|---|
| | | or average | | | | | | |
| | | particle | Product name or | Example | Example | Example | Example | Example |
| | | diameter | substance name | 10 | 11 | 12 | 13 | 14 |
| (A) Epoxy resin | | a1 | YDF8170 | 29.1 | 29.0 | 25.5 | 29.1 | 29.1 |
| (B) Curing agent | | b1 | HDAA | 10.9 | 10.9 | 9.5 | 10.9 | 10.9 |
| (C) | (C1) Large- | 0.6 μm | SE2200SEJ | 60.0 | 60.0 | 60.0 | 60.0 | 60.0 |

| | | | | | | | |
|---|---|---|---|---|---|---|---|
| Filler | diameter filler | Surface treatment agent for | g1 | g1 | g1 | g1 | g1 |
| | | (C1) large-diameter filler | | | | | |

| (D) Ionic compound | d1 | 1-Butyl-1-methylpyrrolidinium | 0.005 | 0.012 | 5 | | |
|---|---|---|---|---|---|---|---|
| | | bis(trifluoromethylsulfonyl)imide | | | | | |
| | d6 | Methyltrioctylammonium | | | | 0.001 | 0.003 |
| | | bis(trifluoromethanesulfonyl)imide | | | | | |

| Equivalent ratio | | 0.9 | 0.9 | 0.9 | 0.9 | 0.9 |
|---|---|---|---|---|---|---|
| Total | | 100.0 | 100.0 | 100.0 | 100.0 | 100.0 |
| Filler distribution index | | 92 | 94 | 84 | 76 | 78 |
| Viscosity | 50 rpm (Pa · s) | 15.0 | 14.8 | 14.2 | 15.0 | 15.2 |
| | 5 rpm (Pa · s) | 12.0 | 11.0 | 10.2 | 11.4 | 11.2 |
| T.I. | | 0.8 | 0.7 | 0.7 | 0.8 | 0.7 |
| Injectability (sec.) | 50 μmGap | 146 | 144 | 137 | 147 | 145 |
| @20 mm 110° C. | 20 μmGap | 240 | 235 | 220 | 246 | 245 |

| | | | | | |
|---|---|---|---|---|---|
| Cured product appearance | A | A | B | A | A |

| | | Abbreviation | | | | | |
|---|---|---|---|---|---|---|---|
| | | or average | | | | | |
| | | particle | Product name or | Example | Example | Example | Example |
| | | diameter | substance name | 15 | 16 | 17 | 18 |
| (A) Epoxy resin | | a1 | YDF8170 | 29.1 | 29.5 | 28.0 | 25.5 |
| (B) Curing agent | | b1 | HDAA | 10.9 | 10.4 | 9.0 | 9.5 |
| (C) | (C1) Large- | 0.6 μm | SE2200SEJ | 60.0 | 60.0 | 60.0 | 60.0 |

| | | | | | | |
|---|---|---|---|---|---|---|
| Filler | diameter filler | Surface treatment agent for | g1 | g1 | g1 | g1 |
| | | (C1) large-diameter filler | | | | |

| (D) Ionic compound | d1 | 1-Butyl-1-methylpyrrolidinium | | | | |
|---|---|---|---|---|---|---|
| | | bis(trifluoromethylsulfonyl)imide | | | | |
| | d6 | Methyltrioctylammonium | 0.005 | 0.12 | 3 | 5 |
| | | bis(trifluoromethanesulfonyl)imide | | | | |

| Equivalent ratio | | 0.9 | 0.9 | 0.9 | 0.9 |
|---|---|---|---|---|---|
| Total | | 100.0 | 100.0 | 100.0 | 100.0 |
| Filler distribution index | | 80 | 84 | 85 | 75 |
| Viscosity | 50 rpm (Pa · s) | 15.0 | 14.6 | 14.0 | 14.1 |
| | 5 rpm (Pa · s) | 11.0 | 10.7 | 10.0 | 10.4 |
| T.I. | | 0.7 | 0.7 | 0.7 | 0.7 |
| Injectability (sec.) | 50 μmGap | 143 | 140 | 135 | 138 |
| @20 mm 110° C. | 20 μmGap | 244 | 242 | 230 | 237 |

| | | | | |
|---|---|---|---|---|
| Cured product appearance | A | A | A | B |

TABLE 3

| | | Abbreviation | | | | | |
|---|---|---|---|---|---|---|---|
| | | or average | | | | | |
| | | particle | Product name or | Example | Example | Example | Example |
| | | diameter | substance name | 19 | 20 | 21 | 22 |
| (A) Epoxy resin | | a1 | YDF8170 | | | | |
| | | a2 | EXA-850CRP | 29.0 | | | |
| | | a3 | HP4032D | | 28.1 | | |
| | | a4 | iER630 | | | 24.5 | 14.8 |
| | | a5 | YX7400 | | | | 14.0 |
| (B) Curing agent | | b1 | HDAA | 9.8 | 10.7 | 14.3 | 10.0 |
| | | b2 | ETHACURE 100 | | | | |
| | | b3 | HN5500 | | | | |
| | | b4 | MEH8005 | | | | |
| (C) | (C1) Large- | 0.6 μm | SE2200SEJ | 60.0 | 60.0 | 60.0 | 60.0 |

| | | | | | | |
|---|---|---|---|---|---|---|
| Filler | diameter filler | Surface treatment agent for | g1 | g1 | g1 | g1 |
| | | (C1) large-diameter filler | | | | |

| | | | | | | |
|---|---|---|---|---|---|---|
| (D) Ionic compound | d6 | Methyltrioctylammonium | 1.2 | 1.2 | 1.2 | 1.2 |
| | | bis(trifluoromethanesulfonyl)imide | | | | |

| Equivalent ratio | | 0.9 | 0.9 | 0.9 | 0.9 |
|---|---|---|---|---|---|
| Total | | 100.0 | 100.0 | 100.0 | 100.0 |
| Filler distribution index | | 78 | 87 | 81 | 98 |
| Viscosity | 50 rpm (Pa · s) | 45.0 | 186.8 | 12.1 | 8.0 |
| | 5 rpm (Pa · s) | 36.0 | 162.0 | 9.8 | 12.0 |
| T.I. | | 0.8 | 0.9 | 0.8 | 1.5 |
| Injectability (sec.) | 50 μmGap | 117 | 145 | 89 | 90 |
| @20 mm 110° C. | 20 μmGap | 196 | 251 | 165 | 180 |

| | | | | |
|---|---|---|---|---|
| Cured product appearance | A | A | A | A |

| | | Abbreviation | | | | |
|---|---|---|---|---|---|---|
| | | or average | | | | |
| | | particle | Product name or | Example | Example | Example |
| | | diameter | substance name | 23 | 24 | 25 |
| (A) Epoxy resin | | a1 | YDF8170 | 31.4 | 19.9 | 26.2 |
| | | a2 | EXA-850CRP | | | |
| | | a3 | HP4032D | | | |
| | | a4 | iER630 | | | |
| | | a5 | YX7400 | | | |
| (B) Curing agent | | b1 | HDAA | | | |
| | | b2 | ETHACURE 100 | 7.4 | | |
| | | b3 | HN5500 | | 18.9 | |
| | | b4 | MEH8005 | | | 12.6 |
| (C) | (C1) Large- | 0.6 μm | SE2200SEJ | 60.0 | 60.0 | 60.0 |

| | | | | | |
|---|---|---|---|---|---|
| Filler | diameter filler | Surface treatment agent for | g1 | g1 | g1 |
| | | (C1) large-diameter filler | | | |

| | | | | | |
|---|---|---|---|---|---|
| (D) Ionic compound | d6 | Methyltrioctylammonium | 1.2 | 1.2 | 1.2 |
| | | bis(trifluoromethanesulfonyl)imide | | | |

| Equivalent ratio | | 0.9 | 0.9 | 0.9 |
|---|---|---|---|---|
| Total | | 100.0 | 100.0 | 100.0 |
| Filler distribution index | | 88 | 90 | 76 |
| Viscosity | 50 rpm (Pa · s) | 11.2 | 5.4 | 8.0 |
| | 5 rpm (Pa · s) | 11.0 | 6.0 | 7.9 |
| T.I. | | 1.0 | 1.1 | 1.0 |
| Injectability (sec.) | 50 μmGap | 80 | 84 | 47 |
| @20 mm 110° C. | 20 μmGap | 126 | 164 | 69 |

| | | | |
|---|---|---|---|
| Cured product appearance | A | A | A |

TABLE 4

| | | Abbreviation | | | | | |
|---|---|---|---|---|---|---|---|
| | | or average | | | | | |
| | | particle | Product name or | Example | Example | Example | Example |
| | | diameter | substance name | 26 | 27 | 28 | 29 |
| (A) Epoxy resin | | a1 | YDF8170 | 28.5 | 28.5 | 46.7 | 21.1 |
| (B) Curing agent | | b1 | HDAA | 10.3 | 10.3 | 17.2 | 7.8 |
| (C) | (C1) Large- | 0.3 μm | SE1050SEO | 60.0 | | | |
| Filler | diameter filler | 0.6 μm | SE2300 | | | | |
| | | 0.6 μm | SE2200SEJ | | | 35.0 | |
| | | 0.6 μm | SE2200SME | | | | |
| | | 2.0 μm | SE5200SEE | | 60.0 | | 70.0 |
| | | Surface treatment agent for | | g1 | g1 | g1 | g1 |
| | | (C1) large-diameter filler | | | | | |
| | (C2) Small- | 10 nm | YA010A | | | | |
| | diameter filler | 100 nm | YC100C | | | | |
| (D) Ionic compound | | d6 | Methyltrioctylammonium | 1.2 | 1.2 | 1.2 | 1.2 |
| | | | bis(trifluoromethanesulfonyl)imide | | | | |
| Equivalent ratio | | | | 0.9 | 0.9 | 0.9 | 0.9 |
| Total | | | | 100.0 | 100.0 | 100.0 | 100.0 |
| Filler distribution index | | | | 92 | 76 | 80 | 90 |
| Viscosity | | 50 rpm (Pa · s) | | 45.8 | 13.6 | 3.6 | 30.0 |
| | | 5 rpm (Pa · s) | | 22.0 | 10.0 | 4.0 | 20.0 |
| T.I. | | | | 0.5 | 0.7 | 1.1 | 0.7 |
| Injectability (sec.) | | 50 μmGap | | 166 | 90 | 47 | 50 |
| @20 mm 110° C. | | 20 μmGap | | 311 | 105 | 70 | 80 |
| Cured product appearance | | | | A | A | A | A |
| | | Abbreviation | | | | | |
| | | or average | | | | | |
| | | particle | Product name or | Example | Example | Example | Example |
| | | diameter | substance name | 30 | 31 | 32 | 33 |
| (A) Epoxy resin | | a1 | YDF8170 | 28.5 | 28.5 | 30.5 | 24.3 |
| (B) Curing agent | | b1 | HDAA | 10.3 | 10.3 | 8.3 | 14.5 |
| (C) | (C1) Large- | 0.3 μm | SE1050SEO | | | | |
| Filler | diameter filler | 0.6 μm | SE2300 | 60.0 | | | |
| | | 0.6 μm | SE2200SEJ | | | 60.0 | 60.0 |
| | | 0.6 μm | SE2200SME | | 60.0 | | |
| | | 2.0 μm | SE5200SEE | | | | |
| | | Surface treatment agent for | | None | g2 | g1 | g1 |
| | | (C1) large-diameter filler | | | | | |
| | (C2) Small- | 10 nm | YA010A | | | | |
| | diameter filler | 100 nm | YC100C | | | | |
| (D) Ionic compound | | d6 | Methyltrioctylammonium | 1.2 | 1.2 | 1.2 | 1.2 |
| | | | bis(trifluoromethanesulfonyl)imide | | | | |
| | | Equivalent ratio | | 0.9 | 0.9 | 0.7 | 1.5 |
| Total | | | | 100.0 | 100.0 | 100.0 | 100.0 |
| Filler distribution index | | | | 75 | 99 | 84 | 97 |
| Viscosity | | 50 rpm (Pa · s) | | 18.1 | 24.6 | 17.2 | 19.2 |
| | | 5 rpm (Pa · s) | | 13.4 | 32.0 | 14.3 | 14.0 |
| T.I. | | | | 0.7 | 1.3 | 0.8 | 0.7 |
| Injectability (sec.) | | 50 μmGap | | 175 | 127 | 98 | 88 |
| @20 mm 110° C. | | 20 μmGap | | 310 | 334 | 135 | 132 |
| Cured product appearance | | | | A | A | A | A |
| | | Abbreviation | | | | | |
| | | or average | | | | | |
| | | particle | Product name or | Example | Example | Example | Example |
| | | diameter | substance name | 34 | 35 | 36 | 37 |
| (A) Epoxy resin | | a1 | YDF8170 | 28.5 | 28.5 | 28.5 | 28.5 |
| (B) Curing agent | | b1 | HDAA | 10.3 | 10.3 | 10.3 | 10.3 |
| (C) | (C1) Large- | 0.3 μm | SE1050SEO | | | | |
| Filler | diameter filler | 0.6 μm | SE2300 | | | | |
| | | 0.6 μm | SE2200SEJ | 58.0 | 58.0 | 58.0 | 45.0 |
| | | 0.6 μm | SE2200SME | | | | |
| | | 2.0 μm | SE5200SEE | | | | |
| | | Surface treatment agent for | | g1 | g1 | g1 | g1 |
| | | (C1) large-diameter filler | | | | | |
| | (C2) Small- | 10 nm | YA010A | 2.0 | | 1.0 | 15.0 |
| | diameter filler | 100 nm | YC100C | | 2.0 | 1.0 | |

| | | | | | | |
|---|---|---|---|---|---|---|
| (D) Ionic compound | d6 | Methyltrioctylammonium | 1.2 | 1.2 | 1.2 | 1.2 |

bis(trifluoromethanesulfonyl)imide

| Equivalent ratio | | 0.9 | 0.9 | 0.9 | 0.9 |
|---|---|---|---|---|---|
| Total | | 100.0 | 100.0 | 100.0 | 100.0 |
| Filler distribution index | | 92 | 94 | 96 | 90 |
| Viscosity | 50 rpm (Pa · s) | 25.4 | 20.3 | 20.0 | 31.2 |
| | 5 rpm (Pa · s) | 18.0 | 16.0 | 18.0 | 32.0 |
| T.I. | | 0.7 | 0.8 | 0.8 | 1.0 |
| Injectability (sec.) | 50 μmGap | 105 | 120 | 130 | 176 |
| @20 mm 110° C. | 20 μmGap | 210 | 240 | 250 | 383 |

| | | | | |
|---|---|---|---|---|
| Cured product appearance | A | A | A | A |

TABLE 5

| | | Abbreviation | | | | |
|---|---|---|---|---|---|---|
| | | or average | | | | |
| | | particle | Product name or | Example | Example | Example |
| | | diameter | substance name | 38 | 39 | 40 |
| (A) Epoxy resin | | a1 | YDF8170 | 28.1 | 28.1 | 28.1 |
| (B) Curing agent | | b1 | HDAA | 10.3 | 10.3 | 10.4 |
| (C) | (C1) Large- | 0.6 μm | SE2200SEJ | 60.0 | 60.0 | 60.0 |
| Filler | diameter filler | Surface treatment agent for | | g1 | g1 | g1 |
| | | (C1) large-diameter filler | | | | |
| (D) Ionic compound | | d6 | Methyltrioctylammonium | 1.2 | 1.2 | 1.2 |
| | | | bis(trifluoromethanesulfonyl)imide | | | |
| (E) Additive | | e1 | MX137 | | | |
| | | e2 | MX965 | | | |
| | | e3 | 2P4MZ | | 0.4 | |
| | | e4 | KBM403 | | | |
| | | e5 | CG1400 | 0.4 | | |
| | | e6 | TPP | | | 0.3 |
| Equivalent ratio | | | | 0.9 | 0.9 | 0.9 |
| Total | | | | 100.0 | 100.0 | 100.0 |
| Filler distribution index | | | | 86 | 80 | 78 |
| Viscosity | | 50 rpm (Pa · s) | | 19.8 | 14.2 | 14.0 |
| | | 5 rpm (Pa · s) | | 16.0 | 10.2 | 9.6 |
| T.I. | | | | 0.8 | 0.7 | 0.7 |
| Injectability (sec.) | | 50 μmGap | | 122 | 140 | 130 |
| @20 mm 110° C. | | 20 μmGap | | 175 | 240 | 210 |
| Cured product appearance | | | | A | A | A |
| | | Abbreviation | | | | |
| | | or average | | | | |
| | | particle | Product name or | Example | Example | Example |
| | | diameter | substance name | 41 | 42 | 43 |
| (A) Epoxy resin | | a1 | YDF8170 | 28.2 | 28.2 | 28.1 |
| (B) Curing agent | | b1 | HDAA | 10.3 | 10.3 | 10.4 |
| (C) | (C1) Large- | 0.6 μm | SE2200SEJ | 60.0 | 60.0 | 60.0 |

| | | | | | |
|---|---|---|---|---|---|
| Filler | diameter filler | Surface treatment agent for | g1 | g1 | g1 |
| | | (C1) large-diameter filler | | | |

| (D) Ionic compound | d6 | Methyltrioctylammonium | 1.2 | 1.2 | 1.2 |
|---|---|---|---|---|---|
| | | bis(trifluoromethanesulfonyl)imide | | | |
| (E) Additive | e1 | MX137 | 0.3 | | |
| | e2 | MX965 | | 0.3 | |
| | e3 | 2P4MZ | | | |
| | e4 | KBM403 | | | 0.3 |
| | e5 | CG1400 | | | |
| | e6 | TPP | | | |

| Equivalent ratio | | 0.9 | 0.9 | 0.9 |
|---|---|---|---|---|
| Total | | 100.0 | 100.0 | 100.0 |
| Filler distribution index | | 78 | 82 | 79 |
| Viscosity | 50 rpm (Pa · s) | 20.4 | 16.0 | 14.7 |
| | 5 rpm (Pa · s) | 18.0 | 12.0 | 10.9 |
| T.I. | | 0.9 | 0.8 | 0.7 |
| Injectability (sec.) | 50 μmGap | 180 | 132 | 143 |
| @20 mm 110° C. | 20 μmGap | 310 | 239 | 239 |

| | | | |
|---|---|---|---|
| Cured product appearance | A | A | A |

TABLE 6

| | | Abbreviation | | | | | |
|---|---|---|---|---|---|---|---|
| | | or average | | | | | |
| | | particle | Product name or | Example | Example | Example | Example |
| | | diameter | substance name | 44 | 45 | 46 | 47 |
| (A) Epoxy resin | | a1 | YDF8170 | 28.5 | 28.5 | 28.5 | 28.5 |
| (B) Curing agent | | b1 | HDAA | 10.3 | 10.3 | 10.3 | 10.3 |
| (C) | (C1) Large- | 0.6 μm | SE2200SEJ | 60.0 | 60.0 | 60.0 | 60.0 |

| | | | | | | |
|---|---|---|---|---|---|---|
| Filler | diameter filler | Surface treatment agent for | g1 | g1 | g1 | g1 |
| | | (C1) large-diameter filler | | | | |

| (D) Ionic compound | d9 | Methyltrioctylammonium | 1.2 | | | |
|---|---|---|---|---|---|---|
| | | tosylate | | | | |
| | d10 | Tributyldodecylphosphonium | | 1.2 | | |
| | | tosylate | | | | |
| | d11 | Tributyldodecylphosphonium | | | 1.2 | |
| | | dodecylbenzenesulfonate | | | | |
| | d12 | N-Oleyl-N,N-di(2- | | | | 1.2 |
| | | hydroxyethyl)-N-methylammonium | | | | |
| | | bis(trifluoromethanesulfonyl)imide | | | | |

| Equivalent ratio | | 0.9 | 0.9 | 0.9 | 0.9 |
|---|---|---|---|---|---|
| Total | | 100.0 | 100.0 | 100.0 | 100.0 |
| Filler distribution index | | 88 | 90 | 91 | 88 |
| Viscosity | 50 rpm (Pa · s) | 18.4 | 18.2 | 17.8 | 18.4 |
| | 5 rpm (Pa · s) | 14.0 | 14.0 | 14.0 | 14.0 |
| T.I. | | 0.8 | 0.8 | 0.8 | 0.8 |
| Injectability (sec.) | 50 μmGap | 150 | 148 | 152 | 150 |
| @20 mm 110° C. | 20 μmGap | 240 | 238 | 242 | 240 |

| | | | | |
|---|---|---|---|---|
| Cured product appearance | A | A | A | A |

| | | Abbreviation | | | | | |
|---|---|---|---|---|---|---|---|
| | | or average | | | | | |
| | | particle | Product name or | Example | Example | Example | Example |
| | | diameter | substance name | 48 | 49 | 50 | 51 |
| (A) Epoxy resin | | a1 | YDF8170 | 28.5 | 28.5 | 28.5 | 28.5 |
| (B) Curing agent | | b1 | HDAA | 10.3 | 10.3 | 10.3 | 10.3 |
| (C) | (C1) Large- | 0.6 μm | SE2200SEJ | 60.0 | 60.0 | 60.0 | 60.0 |

| | | | | | | |
|---|---|---|---|---|---|---|
| Filler | diameter filler | Surface treatment agent for | g1 | g1 | g1 | g1 |
| | | (C1) large-diameter filler | | | | |

| (D) Ionic compound | d13 | Tributyl[3- | 1.2 | | | |
|---|---|---|---|---|---|---|
| | | (trimethoxyxilyl)propyl]phosphonium | | | | |
| | | 1,1,1-trifluoro-N- | | | | |
| | | [(trifluoromethyl)sulfonyl] | | | | |
| | | methanesulfonamide | | | | |
| | d14 | Methyltrioctylammonium | | 1.2 | | |
| | | imidodisulfuryl fluoride | | | | |
| | d15 | Tetrabutylammonium | | | 1.2 | |
| | | hexafluorophosphate | | | | |
| | d16 | Methyltrioctylammonium | | | | 1.2 |
| | | hexafluorophosphate | | | | |

| Equivalent ratio | | 0.9 | 0.9 | 0.9 | 0.9 |
|---|---|---|---|---|---|
| Total | | 100.0 | 100.0 | 100.0 | 100.0 |
| Filler distribution index | | 90 | 92 | 93 | 92 |
| Viscosity | 50 rpm (Pa · s) | 18.2 | 16.8 | 23.8 | 19.8 |
| | 5 rpm (Pa · s) | 14.0 | 10.0 | 16.0 | 14.0 |
| T.I. | | 0.8 | 0.6 | 0.7 | 0.7 |
| Injectability (sec.) | 50 μmGap | 148 | 100 | 102 | 105 |
| @20 mm 110° C. | 20 μmGap | 238 | 196 | 193 | 167 |

| | | | | |
|---|---|---|---|---|
| Cured product appearance | A | A | A | A |

1. An epoxy resin composition, comprising:
(A) an epoxy resin;
(B) a curing agent;
(C) a filler; and
(D) an ionic compound in which at least one of a cation or an anion is organic matter.

2. The epoxy resin composition according to claim 1, wherein (D) the ionic compound contains at least one selected from the group consisting of: a pyridinium-based ionic compound; an imidazolium-based ionic compound; an ammonium-based ionic compound; a phosphonium-based ionic compound; a pyrrolidinium-based ionic compound; a piperidinium-based ionic compound; a sulfonate-based ionic compound;
and an iodine-based ionic compound.

3. The epoxy resin composition according to claim 1, wherein (D) the ionic compound contains
<i>at least one kind of cation selected from the group consisting of: a pyridinium-based cation; an imidazolium-based cation; an ammonium-based cation; a pyrrolidinium-based cation; a piperidinium-based cation; and a phosphonium-based cation, and
<ii>at least one kind of anion selected from the group consisting of: a sulfonylimide-based anion; a sulfonate-based anion; a hexafluorophosphate anion; a bis(trifluoromethylsulfonyl)imide anion; an imidodisulfuryl fluoride anion; and an iodine anion.

4. The epoxy resin composition according to claim 1, wherein (D) the ionic compound is an ionic liquid.

5. The epoxy resin composition according to claim 1, wherein (D) the ionic compound has a reactive group.

6. The epoxy resin composition according to claim 1, wherein a content ratio of (D) the ionic compound is from 0.0001 mass % to 3.1 mass % with respect to an entire amount of the epoxy resin composition.

7. The epoxy resin composition according to claim 1, wherein a content ratio of (D) the ionic compound is 0.001 mass % or more and 1.2 mass % or less with respect to an entire amount of the epoxy resin composition.

8. The epoxy resin composition according to claim 1, wherein (D) the ionic compound contains at least one selected from the group consisting of:
(D-1) 1-butyl-1-methylpyrrolidinium bis(trifluoromethylsulfonyl)imide;
(D-2) tributyldodecylphosphonium bis(trifluoromethanesulfonyl)imide;
(D-3) 1-hexyl-4-methylpyridinium bis(trifluoromethanesulfonyl)imide;
(D-4) trimethylpropylammonium bis(trifluoromethanesulfonyl)imide;
(D-5) 4-(2-ethoxyethyl)-4-methylmorpholinium bis(trifluoromethanesulfonyl)imide;
(D-6) methyltrioctylammonium bis(trifluoromethanesulfonyl)imide;
(D-7) tributylmethylammonium bis(trifluoromethanesulfonyl)imide;
(D-8) 1-butyl-3-dodecylimidazolium bis(trifluoromethanesulfonyl)imide;
(D-9) methyltrioctylammonium tosylate;
(D-10) tributyldodecylphosphonium tosylate;
(D-11) tributyldodecylphosphonium dodecylbenzenesulfonate;
(D-12) N-oleyl-N,N-di(2-hydroxyethyl)-N-methylammonium bis(trifluoromethanesulfonyl)im ide;
(D-13) tributyl[3-(trimethoxysilyl)propyl]phosphonium 1,1,1-trifluoro-N-[(trifluoromethyl)sulfonyl]methanesulfonamide;
(D-14) methyltrioctylammonium imidodisulfuryl fluoride;
(D-15) tetrabutylammonium hexafluorophosphate; and
(D-16) methyltrioctylammonium hexafluorophosphate.

9. The epoxy resin composition according to claim 1, wherein (A) the epoxy resin contains a liquid epoxy resin.

10. The epoxy resin composition according to claim 1, wherein (A) the epoxy resin contains at least one selected from the group consisting of: a bisphenol F-type epoxy resin; a bisphenol A-type epoxy resin; a biphenyl-type epoxy resin; an aminophenol-type epoxy resin; and a naphthalene-type epoxy resin.

11. The epoxy resin composition according to claim 1,
wherein the epoxy resin composition comprises (C1) a large-diameter filler having an average particle diameter of 0.2 μm or more as (C) the filler, and
wherein a content ratio of (C1) the large-diameter filler is from 35 mass % to 70 mass % with respect to an entire amount of the epoxy resin composition.

12. The epoxy resin composition according to claim 11, wherein the average particle diameter of (C1) the large-diameter filler is from 0.2 μm to 3.0 μm.

13. The epoxy resin composition according to claim 1,
wherein the epoxy resin composition comprises (C2) a small-diameter filler having an average particle diameter of less than 0.2 μm as (C) the filler, and
wherein the average particle diameter of (C2) the small-diameter filler is from 5 nm to 120 nm.

14. The epoxy resin composition according to claim 1, further comprising (E) an additive, wherein the epoxy resin composition

15. The epoxy resin composition according to claim 1, wherein the epoxy resin composition is used as a sealing material for a semiconductor device.

16. A semiconductor device, comprising:
a substrate;
a semiconductor element arranged on the substrate; and
a cured product of an epoxy resin composition sealing a gap between the semiconductor element and the substrate,
wherein the epoxy resin composition contains
(A) an epoxy resin;
(B) a curing agent;
(C) a filler; and
(D) an ionic compound in which at least one of a cation or an anion is organic matter.

17. A method of producing a semiconductor device, comprising the steps of:
filling a gap between a substrate and a semiconductor element arranged on the substrate with an epoxy resin composition; and
curing the epoxy resin composition,
wherein the epoxy resin composition contains
(A) an epoxy resin;
(B) a curing agent;
(C) a filler; and
(D) an ionic compound in which at least one of a cation or an anion is organic matter.
